(19) United States
(12) Patent Application Publication
(10) Pub. No.: US 2008/0111171 A1
(43) Pub. Date: May 15, 2008

(54) Node structures under capacitor in ferroelectric random access memory device and methods of forming the same

(75) Inventors: Heung-Jin Joo, Suwon-si (KR); Yoon-Jong Song, Seoul (KR); Ki-Nam Kim, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/811,931

(22) Filed: Jun. 12, 2007

(30) Foreign Application Priority Data
Nov. 9, 2006 (KR) 1020060110551

(51) Int. Cl. H01L 29/94; H01L 21/02

(52) U.S. Cl. 257/295; 438/3; 257/E27.088; 257/E21.649

(57) ABSTRACT

In a node structure under a capacitor in a ferroelectric random access memory device and a method of forming the same, top surfaces of the node structures are disposed at substantially the same level as a top surface of an interlayer insulating layer surrounding the node structures, and thus crystal growth of a ferroelectric in the capacitor can be stabilized. To this end, a node insulating pattern is formed on a semiconductor substrate. A node defining pattern surrounding the node insulating pattern is disposed under the node insulating pattern. A node conductive pattern is disposed between the node defining pattern and the node insulating pattern.

### CROSS-REFERENCE TO RELATED APPLICATION

This patent application claims priority from Korean Patent Application No. 10-2006-0110551, filed in the Korean Intellectual Property Office on Nov. 09, 2006, the contents of which are hereby incorporated by reference in their entirety.

### BACKGROUND OF THE INVENTION

1. Field of the Invention

The present invention relates to node structures under a capacitor in a semiconductor device, and more particularly, to node structures under a capacitor in a ferroelectric random access memory device (FRAM) and methods of forming the same.

2. Description of the Related Art

Generally, a ferroelectric random access memory (FRAM) device is formed by using a ferroelectric instead of an insulating dielectric in a capacitor of a dynamic random access memory (DRAM) device. To this end, the FRAM device may have a different peripheral structure around the capacitor than the DRAM device. Moreover, the FRAM device may input or output data to or from the capacitor using the desired hysteresis characteristics from the ferroelectric according to electric polarization of the ferroelectric.

However, the FRAM devices may have a ferroelectric which shows undesired hysteresis characteristics after forming the capacitor, in case that top surfaces of a node structure under the capacitor and an interlayer insulating layer surrounding the structure are not disposed at substantially the same level. This is because the ferroelectric is crystal-grown through thermal treatment during the forming of the capacitor corresponding to a step height between the top surfaces of the interlayer insulating layer and the node structure. Thus, the step height between the top surfaces of the interlayer insulating layer and the node structure affects electrical characteristics of the FRAM device.

A node structure under a capacitor is disclosed in U.S. Pat. No. 6,075,264 by Bon Jae Koo. According to U.S. Pat. No. 6,075,264, an interlayer insulating layer is disposed on a semiconductor substrate. A contact hole passing through the interlayer insulating layer is formed. An oxidizable conductive layer and a conductive oxide layer are sequentially disposed, which conformally cover the contact hole, and are disposed on the interlayer insulating layer around the contact hole. A contact plug is formed on the conductive oxide layer to fill the contact hole. A capacitor, which is in contact with the contact plug and the conductive oxide layer, is formed. The capacitor has a ferroelectric.

However, the capacitor may have a ferroelectric showing an undesired hysteresis phenomenon. This is because the capacitor is in contact with the oxidizable conductive layer and the conductive oxide layer, which extend upwardly from the contact hole. That is, the oxidizable conductive layer and the conductive oxide layer are formed to further increase a step height between a top surface of the interlayer insulating layer and an inner wall of the contact hole. Moreover, since the contact plug is formed using the conductive oxide layer as an etch mask, the contact plug may add an additional step height to the step height between the top surface of the interlayer insulating layer and the inner wall of the contact hole.

### SUMMARY OF THE INVENTION

The invention provides node structures under a capacitor in a ferroelectric random access memory device, which is suitable for being surrounded by an interlayer insulating layer and disposed at substantially the same level as a top surface of the interlayer insulating layer.

The invention also provides methods of forming a node structure under a capacitor in a ferroelectric random access memory device, which is surrounded by an interlayer insulating layer to be disposed at substantially the same level as a top surface of the interlayer insulating layer, and thus capable of stabilizing crystal growth of the ferroelectric in the capacitor.

According to one aspect, the present invention is directed to a node structures which includes a node insulating pattern disposed on a semiconductor substrate. A node conductive pattern is disposed under the node insulating pattern and extends along a sidewall of the node insulating pattern. A node defining pattern is disposed under the node conductive pattern and extends along a sidewall of the node conductive pattern. The node insulating pattern, the node conductive pattern, and the node defining pattern have top surfaces disposed at substantially the same level.

In one embodiment, the node defining pattern comprises titanium nitride (TiN), or titanium nitride and titanium (TiN/Ti) which are sequentially stacked.

In one embodiment, the node conductive pattern comprises tungsten (W).

In one embodiment, the node insulating pattern comprises silicon nitride (Si₃N₄), titanium nitride (TiN), or titanium aluminum nitride (TiAlN).

According to another aspect, the present invention is directed to a node structure which includes a node insulating pattern disposed on a semiconductor substrate. A node conductive pattern is disposed along a sidewall of the node insulating pattern. A node defining pattern is disposed under the node conductive pattern and the node insulating pattern to surround the node conductive pattern and the node insulating pattern. The node insulating pattern, the node conductive pattern, and the node defining pattern have top surfaces which are disposed at substantially the same level.

In one embodiment, the node defining pattern comprises titanium nitride (TiN), or titanium nitride and titanium (TiN/Ti) which are sequentially stacked.

In one embodiment, the node conductive pattern comprises tungsten (W).

In one embodiment, the node insulating pattern comprises silicon nitride (Si₃N₄), titanium nitride (TiN), or titanium aluminum nitride (TiAlN).

According to another aspect, the present invention is directed to a node structure having first and second node insulating patterns disposed on a semiconductor substrate. The second node insulating pattern is adjacent to a sidewall of the first node insulating pattern. A node conductive pattern is disposed under the second node insulating pattern and extends along a sidewall of the second node insulating pattern. A node defining pattern is disposed under the node conductive pattern, and the first and second node insulating patterns to surround the node conductive pattern, and the first and second node insulating patterns. The first and second node insulating patterns, the node conductive pattern, and the node defining pattern have top surfaces which are disposed at substantially the same level.

In one embodiment, the node defining pattern comprises titanium nitride (TiN), or titanium nitride and titanium (TiN/Ti) which are sequentially stacked.

In one embodiment, the node conductive pattern comprises tungsten (W).

In one embodiment, the first and second node insulating patterns comprise silicon nitride (Si₃N₄), titanium nitride (TiN), or titanium aluminum nitride (TiAlN).

According to another aspect, the present invention is directed to a method of forming a node structure. The method includes forming an interlayer insulating layer on a semiconductor substrate. A node hole is formed in the interlayer insulating layer to expose the semiconductor substrate. A node defining layer, a node conductive layer, and a node insulating layer are sequentially formed on the interlayer insulating layer to sufficiently fill the node hole. The node conductive layer and the node defining layer are formed to conformally cover the node hole. A node defining pattern, a node conductive pattern, and a node insulating pattern are formed in the node hole by sequentially etching the node insulating layer, the node conductive layer, and the node defining layer so as to expose the interlayer insulating layer. Top surfaces of the node insulating pattern, the node conductive pattern, and the node defining pattern are formed at substantially the same level as a top surface of the interlayer insulating layer.

In one embodiment, the node defining layer comprises titanium nitride (TiN), or titanium nitride and titanium (TiN/Ti) which are sequentially stacked.

In one embodiment, the node conductive layer and the interlayer insulating layer comprise tungsten (W) and silicon oxide (SiO₂), respectively.

In one embodiment, the node insulating layer comprises silicon nitride (Si₃N₄), titanium nitride (TiN), or titanium aluminum nitride (TiAlN).

In one embodiment, forming the node hole comprises: forming a photoresist layer on the interlayer insulating layer, the photoresist layer being formed to have an opening: etching the interlayer insulating layer through the opening using the photoresist layer as an etch mask; and removing the photoresist layer from the semiconductor substrate.

According to another aspect, the present invention is directed to a method of forming a node structure. The method includes forming an interlayer insulating layer on a semiconductor substrate. A node hole is formed in the interlayer insulating layer to expose the semiconductor substrate. A node defining layer and a molding layer are sequentially formed on the interlayer insulating layer to sufficiently fill the node hole. A molding hole is formed in the molding layer to expose the node defining layer. The molding hole is formed to pass through the node hole. A node insulating layer is formed on the molding layer to sufficiently fill the molding hole. A molding pattern and a preliminary node insulating pattern are formed in the node hole by sequentially etching the node insulating layer and the molding layer so as to expose the node defining layer. The molding pattern is removed using the preliminary node insulating pattern and the node defining layer as etch stop layers. A node conductive layer is formed, which covers the preliminary node insulating pattern and the node defining layer and sufficiently fills the node hole. A node defining pattern, a node conductive pattern, and a node insulating pattern are formed in the node hole by etching the node conductive layer, the preliminary node insulating pattern, and the node defining layer so as to expose the interlayer insulating layer. Top surfaces of the node insulating pattern, the node conductive pattern, and the node defining pattern are formed at substantially the same level as a top surface of the interlayer insulating layer.

In one embodiment, the node defining layer comprises titanium nitride (TiN), or titanium nitride and titanium (TiN/Ti) which are sequentially stacked.

In one embodiment, the node conductive layer comprises tungsten (W), and the interlayer insulating layer and the molding layer comprise silicon oxide (SiO₂).

In one embodiment, the node insulating layer comprises silicon nitride (Si₃N₄), titanium nitride (TiN), or titanium aluminum nitride (TiAlN).

In one embodiment, forming the molding hole comprises:forming a photoresist layer on the molding layer, the photoresist layer being formed to have an opening aligned with the node hole; etching the molding layer through the opening using the photoresist layer and the node defining layer as an etch mask and an etch stop layer, respectively; and removing the photoresist layer from the semiconductor substrate.

In one embodiment, forming the node hole comprises: forming a photoresist layer on the interlayer insulating layer, the photoresist layer being formed to have an opening: etching the interlayer insulating layer through the opening using the photoresist layer as an etch mask; and removing the photoresist layer from the semiconductor substrate.

According to another aspect, the present invention is directed to a method of forming a node structure. The method includes forming an interlayer insulating layer on a semiconductor substrate. A node hole is formed in the interlayer insulating layer to expose the semiconductor substrate. A node defining layer and a molding layer are sequentially formed on the interlayer insulating layer to sufficiently fill the node hole. A molding hole is formed in the molding layer to expose the node defining layer. The molding hole is formed to pass through the node hole. A first node insulating layer is formed on the molding hole to sufficiently fill the molding hole. A molding pattern and a first preliminary node insulating pattern are formed by sequentially etching the first node insulating layer and the molding layer so as to expose the node defining layer. The molding pattern is removed using the first preliminary node insulating pattern and the node defining layer as an etch stop layer. A node conductive layer and a second node insulating layer are sequentially formed on the first preliminary node insulating pattern and the node defining layer to sufficiently fill the node hole. The node conductive layer is formed to conformally cover the first preliminary node insulating pattern and the node defining layer. A node defining pattern, a node conductive pattern, and first and second node insulating patterns are formed in the node hole by sequentially etching the second node insulating layer, the node conductive layer, the first preliminary node insulating pattern, and the node defining layer so as to expose the interlayer insulating layer. The first and second node insulating patterns, the node conductive pattern, and the node defining pattern are formed to have top surfaces which are disposed at substantially the same level.

In one embodiment, the node defining layer comprises titanium nitride (TiN), or titanium nitride and titanium (TiN/Ti) which are sequentially stacked.

In one embodiment, the node conductive layer comprises tungsten (W), and the interlayer insulating layer and the molding layer comprise silicon oxide (SiO₂).

In one embodiment, the first and second node insulating layers comprise silicon nitride (Si₃N₄), titanium nitride (TiN), or titanium aluminum nitride (TiAlN).

In one embodiment, forming the molding hole comprises: forming a photoresist layer on the molding layer, the photoresist layer being formed to have an opening aligned with the node hole; etching the molding layer through the opening using the photoresist layer and the node defining layer as an etch mask and an etch stop layer, respectively; and removing the photoresist layer from the semiconductor substrate.

In one embodiment, forming the node hole comprises: forming a photoresist layer on the interlayer insulating layer, the photoresist layer being formed to have an opening: etching the interlayer insulating layer through the opening using the photoresist layer as an etch mask; and removing the photoresist layer from the semiconductor substrate.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a layout view showing a semiconductor device according to the present invention.

FIG. 2 contains cross-sectional views taken along lines I-I′ and II-II′ of FIG. 1.

FIGS. 3 to 6 contain cross-sectional views taken along lines I-I′ and II-II′ of FIG. 1, which illustrate a method of forming a semiconductor device according to a first exemplary embodiment of the present invention.

FIGS. 7 to 9 contain cross-sectional views taken along lines I-I′ and II-II′ of FIG. 1, which illustrate a method of forming a semiconductor device according to a second exemplary embodiment of the present invention.

FIGS. 10 and 11 contain cross-sectional views taken along lines I-I′ and II-II′ of FIG. 1, which illustrate a method of forming a semiconductor device according to a third exemplary embodiment of the present invention.

### DETAILED DESCRIPTION OF PREFERRED EMBODIMENTS OF THE INVENTION

Node structures under a capacitor in a ferroelectric random access memory device of the present invention will now be described more fully hereinafter with reference to the accompanying drawings, in which exemplary embodiments of the invention are shown.

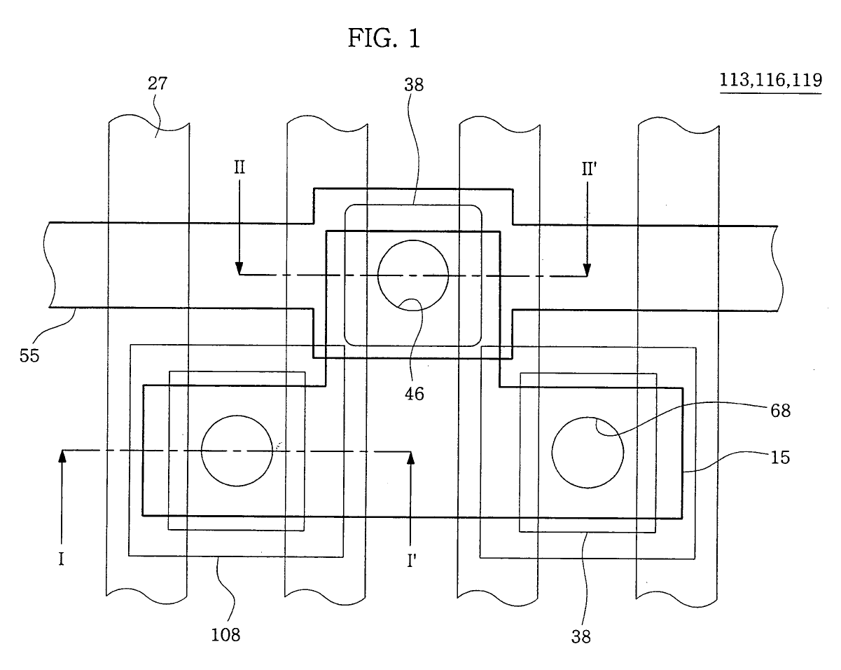

FIG. 1 is a layout view showing a semiconductor device according to the present invention, and FIG. contains cross-sectional views taken along lines I-I′ and II-II′ of FIG. 1.

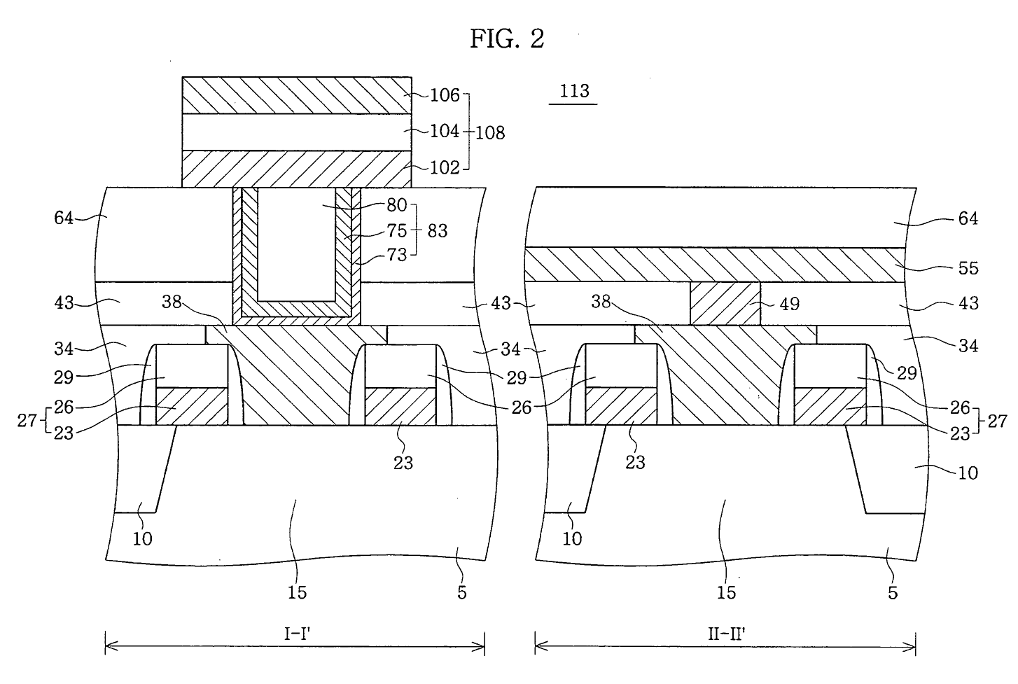

Referring to FIGS. 1 and 2, a ferroelectric random access memory (FRAM) device 113 in accordance with the present invention comprises node structures 83 disposed on a semiconductor substrate 5. Each node structure 83 has a node defining pattern 73, a node conductive pattern 75, and a node insulating pattern 80. The node conductive pattern 75 is disposed under the node insulating pattern 80. The node conductive pattern 75 may be disposed to contact a bottom surface of the node insulating pattern 80 and to extend along sidewalls thereof. The node defining pattern 73 is disposed under the node conductive pattern 75. The node defining pattern 73 may be disposed in contact with a bottom surface of the node conductive pattern 75 and to extend along sidewalls thereof.

The node insulating pattern 80, the node conductive pattern 75, and the node defining pattern 73 have top surfaces, which are disposed at substantially the same level, respectively. The node defining pattern 73 comprises titanium nitride (TiN), or titanium nitride and titanium (TiN/Ti) stacked thereon. The node conductive pattern 75 comprises tungsten (W). The node insulating pattern 80 comprises silicon nitride (Si₃N₄), titanium nitride (TiN), or titanium aluminum nitride (TiAlN).

Referring back to FIGS. 1 and 2, a buried interlayer insulating layer 43 and a planarization interlayer insulating layer 64 are sequentially disposed on the semiconductor substrate 5 to surround the node structures 83. The buried interlayer insulating layer 43 and the planarization interlayer insulating layer 64 comprise silicon oxide (SiO₂). A bit line pattern 55 is disposed between the buried interlayer insulating layer 43 and the planarization interlayer insulating layer 64. The bit line pattern 55 singly comprises doped polysilicon. The bit line pattern 55 may be formed of doped polysilicon and metal silicide stacked thereon. The bit line pattern 55 may also be formed of metal nitride and metal stacked thereon. The planarization interlayer insulating layer 64 may be disposed at the same level as top surfaces of the node structures 83.

Capacitors 108 may be disposed on the planarization interlayer insulating layer 64. The capacitors 108 may be disposed to contact the node structures 83, respectively. Each capacitor 108 has upper and lower electrodes 102 and 106, and a ferroelectric 104 which is interposed between electrodes 102 and 106. The ferroelectric 104 comprises PbZrTiO (PZT). The upper electrode 106 comprises iridium and iridium oxide (Ir/IrO) stacked thereon, strontium oxide, iridium and strontium oxide (SrO/Ir/SrO) which are sequentially stacked, or iridium and strontium oxide (Ir/SrO) stacked thereon. The lower electrode 102 comprises iridium (Ir), or iridium oxide and iridium (IrO/Ir) stacked thereon.

A bit line plug 49 is disposed in the buried interlayer insulating layer 43 to be in contact with the bit line pattern 55. The bit line plug 49 comprises a conductive layer. Pad patterns 38 are disposed under the bit line plug 49 and the node structures 83, respectively. The pad patterns 38 may be disposed to contact the bit line plug 49 and the node structures 83. The pad patterns 38 may be disposed to contact the semiconductor substrate 5. The pad pattern 38 comprises a conductive layer. Gate patterns 27 are disposed on the semiconductor substrate 5 to be located around the pad patterns 38. Each of the gate patterns 27 comprises a gate 23 and a mask pattern 26 stacked thereon.

The mask pattern 26 comprises silicon nitride. The gate 23 comprises doped polysilicon and metal silicide stacked thereon. Gate spacers 29 are disposed on sidewalls of the gate patterns 27, respectively. The gate spacers 29 comprise the same material as the mask pattern 26. A pad interlayer insulating layer 34 covers the gate patterns 27, the gate spacers 29, and the pad patterns 38. The pad interlayer insulating layer 34 comprises the same material as the buried interlayer insulating layer 43. A device isolation layer 10 is disposed under the pad interlayer insulating layer 34. The device isolation layer 10 may be disposed in the semiconductor substrate 5 to define an active region 15.

Methods of forming node structures under a capacitor in a FRAM device according to the present invention will be described with reference to the remaining drawings. To this end, a first exemplary embodiment of the present invention will be first described, and second and third exemplary embodiments will be described in turn.

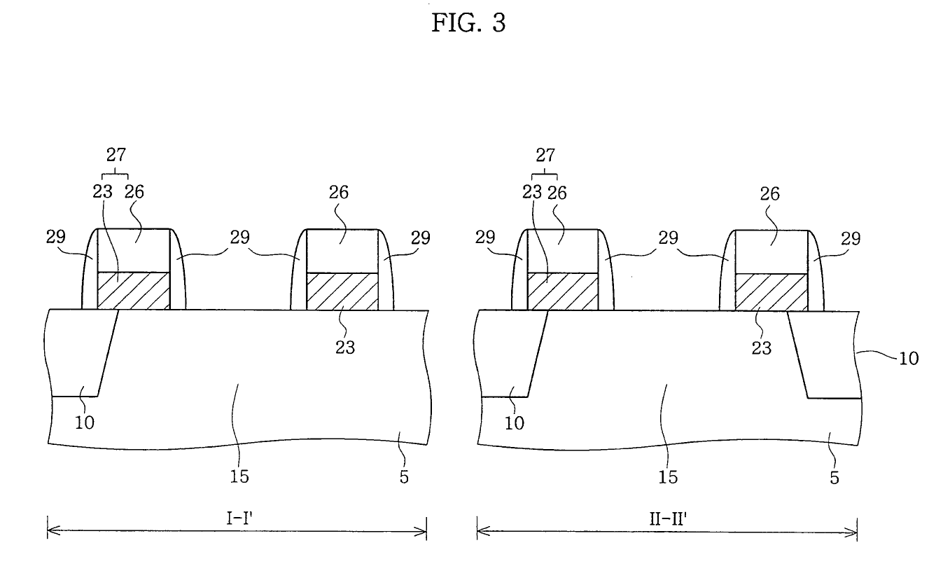

FIGS. 3 to 6 are cross-sectional views taken along lines I-I′ and II-II′ of FIG. 1, which illustrate a method of forming a semiconductor device according to a first exemplary embodiment of the present invention.

Referring to FIGS. 1 and 3, a device isolation layer 10 is formed in a semiconductor substrate 5. The device isolation layer 10 may be formed in the semiconductor substrate 5 to isolate an active region 15. Gate patterns 27 are formed on the device isolation layer 10 to cross the active region 15. Each of the gate patterns 27 comprises a gate 23 and a mask pattern 26, which are sequentially stacked. The mask pattern 26 may be formed of silicon nitride (Si₃N₄). The gate 23 may be formed of doped polysilicon and metal silicide, which are sequentially stacked. Gate spacers 29 are formed on sidewalls of the gate patterns 27, respectively. The gate spacers 29 may be formed of the same material as the mask patterns 26.

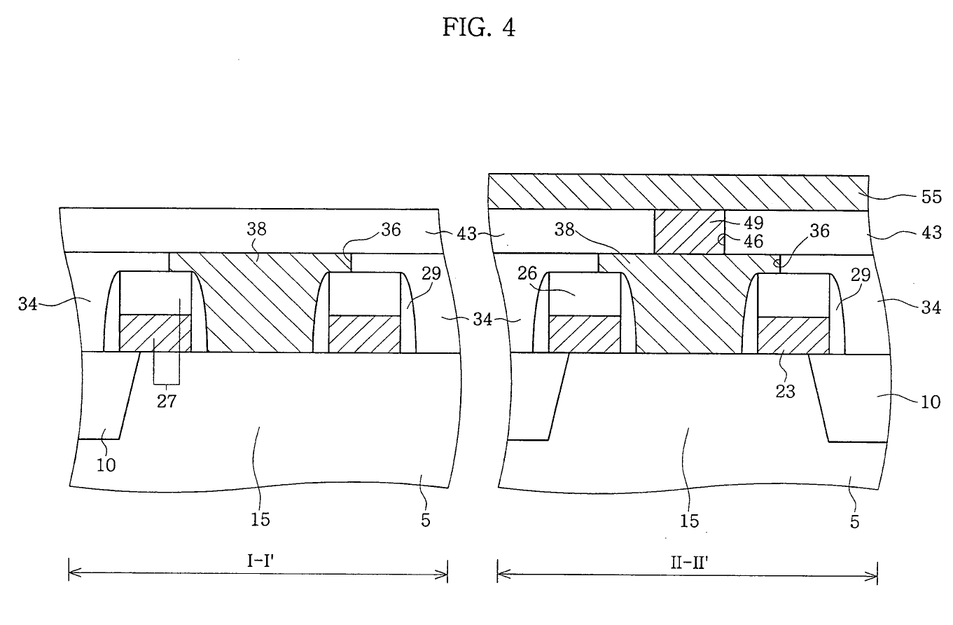

Referring to FIGS. 1 and 4, a pad interlayer insulating layer 34 is formed on the device isolation layer 10 and the active region 15 to cover the gate patterns 27 and the gate spacers 29. The pad interlayer insulating layer 34 may be formed of 20 silicon oxide (SiO₂). Pad holes 36 are formed to pass between the gate patterns 27 through the pad interlayer insulating layer 34. Pad patterns 38 are formed to fill the pad holes. The pad patterns 38 may be formed of a conductive layer. The pad patterns 38 may be formed of doped polysilicon. A buried interlayer insulating layer 43 is formed on the pad interlayer insulating layer 34 to cover the pad patterns 38. The buried interlayer insulating layer 43 may be formed of the same material as the pad interlayer insulating layer 34.

A contact hole 46 is formed to expose one of the pad patterns 38 through the buried interlayer insulating layer 43. A bit line plug 49 is formed to fill the contact hole 46. The bit line plug 49 may be formed of a conductive layer. A bit line pattern 55 is formed on the buried interlayer insulating layer 43 to be in contact with the bit line plug 49. The bit line pattern 55 may be singly formed of doped polysilicon. Also, the bit line pattern 55 may be formed of doped polysilicon and metal silicide, which are sequentially stacked. The bit line pattern 55 may be formed of metal nitride and metal, which are sequentially stacked.

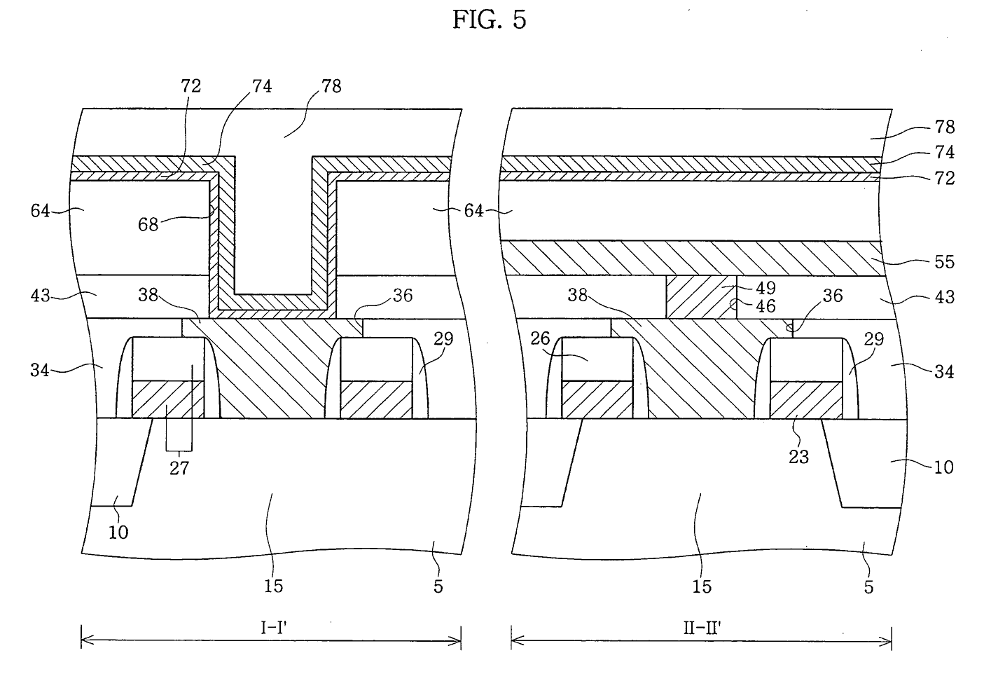

Referring to FIGS. 1 and 5, a planarization interlayer insulating layer 64 is formed on the bit line pattern 55. The planarization interlayer insulating layer 64 may be formed of the same material as the buried interlayer insulating layer 43. A photoresist layer is formed on the planarization interlayer insulating layer 64. The photoresist layer is formed by performing a well known semiconductor photolithography process. The photoresist layer may be formed to have openings, which are aligned with the pad patterns 38 not contacting the bit line plug 49, respectively.

The planarization interlayer insulating layer 64 and the buried interlayer insulating layer 43 are etched through the openings using the photoresist layer as an etch mask, to form node holes 68. The node holes 68 may be formed to respectively expose the pad patterns 38 not contacting the bit line plug 49 through the planarization interlayer insulating layer 64 and the buried interlayer insulating layer 43. The photoresist later is removed from the planarization interlayer insulating layer 64. A node defining layer 72 and a node conductive layer 74 are sequentially formed on the planarization interlayer insulating layer 64 to conformally cover the node holes 68.

A node insulating layer 78 is formed on the node conductive layer 74 to sufficiently fill the node holes 68. To this end, the node insulting layer 78 may be formed of Si₃N₄, TiN, or TiAlN. The node conductive layer 74 may be formed of W. The node defining layer 72 may be formed of TiN, or TiN/Ti.

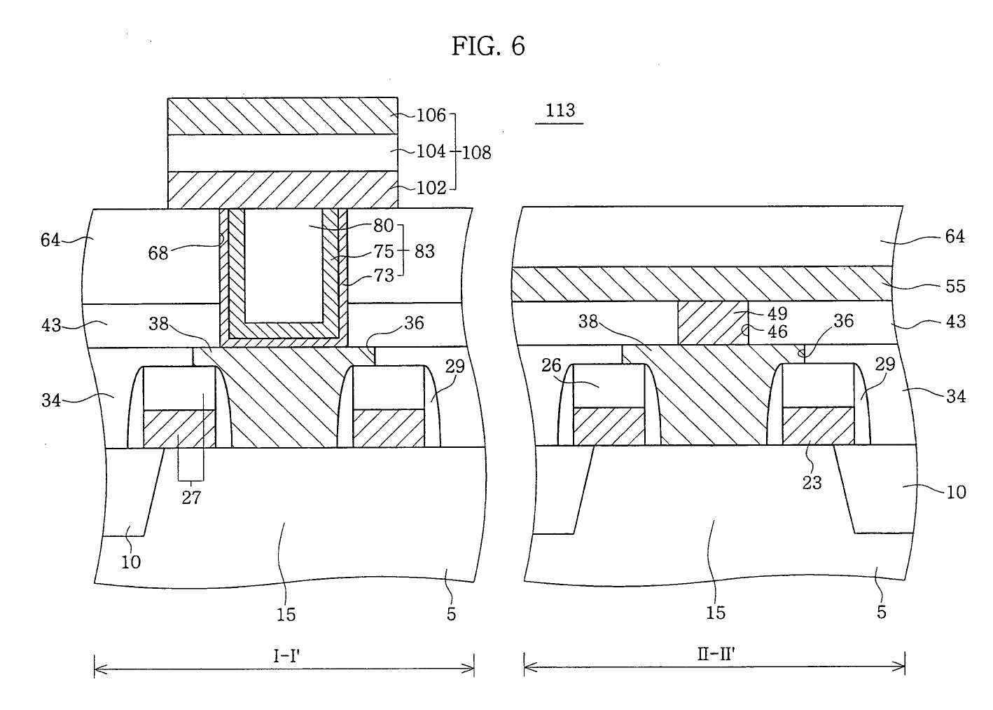

Referring to FIGS. 1 and 6, a planarization process may be sequentially performed on the node insulating layer 78, the node conductive layer 74, and the node defining layer 72 to expose the planarization interlayer insulating layer 64. The planarization process may be performed to form a node defining pattern 73, a node conductive pattern 75, and a node insulating pattern 80 in each node hole 68. The planarization process may be performed using an etching-back or a chemical mechanical polishing technique. Here, the node conductive pattern 75 may be disposed under the node insulating pattern 80, and formed to extend along a sidewall of the node insulating pattern 80. The node defining pattern 73 may be disposed under the node conductive pattern 75, and formed to extend along a sidewall of the node conductive pattern 75.

The node insulating pattern 80, the node conductive pattern 75, and the node defining pattern 73 may be formed to have top surfaces which are disposed at substantially the same level. Moreover, the top surfaces of the node insulating pattern 80, the node conductive pattern 75, and the node defining pattern 73 may be formed at substantially the same level as the top surface of the planarization interlayer insulating layer 64. For this reason, the planarization interlayer insulating layer 64 may be formed to have no step height with the node insulating pattern 80, the node the conductive pattern 75, and the node defining pattern 73. As such, the node defining pattern 73, the node conductive pattern 75 and the node insulating pattern 80 may constitute a node structure 83 according to the first exemplary embodiment of the present invention.

Referring back to FIGS. 1 and 6, as a modified example of the first exemplary embodiment of the present invention, a first etching process is performed on the node insulating layer 78 to expose the node conductive layer 74. The first etching process may form preliminary node insulating patterns (not illustrated) on the node conductive layer 74 to fill the respective node holes 68. The preliminary node insulating patterns may be formed to have top surfaces at the same level as the node conductive layer 74.

A second etching process may be performed on the preliminary node insulating patterns, the node conductive layer 74, and the node defining layer 72 to expose the planarization interlayer insulating layer 64. The second etching process may form the node defining pattern 73, the node conductive pattern 75, and the node insulating pattern 80 in each of the node holes 68. The first and second etching processes may be performed using an etching-back or a chemical mechanical polishing technique. Here, the top surfaces of the node defining pattern 73, the node conductive pattern 75, and the node insulating pattern 80 may be formed to be at the same level as that of the planarization interlayer insulating layer 64. The node defining pattern 73, the node conductive pattern 75, and the node insulating pattern 80 may constitute a node structure 83 according to the modified example of the first exemplary embodiment of the present invention.

Again referring back to FIGS. 1 and 6, capacitors 108 may be formed on the planarization interlayer insulating layer 64 to be in contact with the node structures 83, respectively. Each capacitor 108 may be formed to have upper and lower electrodes 106 and 102, and a ferroelectric 104 between the upper and lower electrodes 106 and 102. The ferroelectric 104 comprises PZT. The upper electrode 106 comprises Ir/IrO, SrO/Ir/SrO, or Ir/SrO. The lower electrode 102 comprises Ir, or IrO₂/Ir.

While forming of the capacitor 108, thermal treatment may be performed at least once on the ferroelectric 104. Here, the top surfaces of the planarization interlayer insulating layer 64, the node defining pattern 73, the node conductive pattern 75, and the node insulating pattern 80 enable crystal growth of the ferroelectric 104 to be stabilized during the thermal treatment. That is, the ferroelectric 104 may be formed parallel to the top surfaces of the planarization interlayer insulating layer 64, the node defining pattern 73, the node conductive pattern 75, and the node insulating pattern 80 in the capacitor 108. Thus, the ferroelectric 104 may have desired hysteresis characteristics, and improve electrical characteristics of the FRAM device 113 according to the first exemplary embodiment of the present invention.

A method of forming a semiconductor device according to a second exemplary embodiment of the present invention will now be described. Here, the second exemplary embodiment of the present invention may be realized differently from the first embodiment of the present invention from after the forming of the node defining layer in FIG. 5. Moreover, description of the second exemplary embodiment of the present invention will use the same reference numerals and symbols for the same materials as the first exemplary embodiment of the present invention.

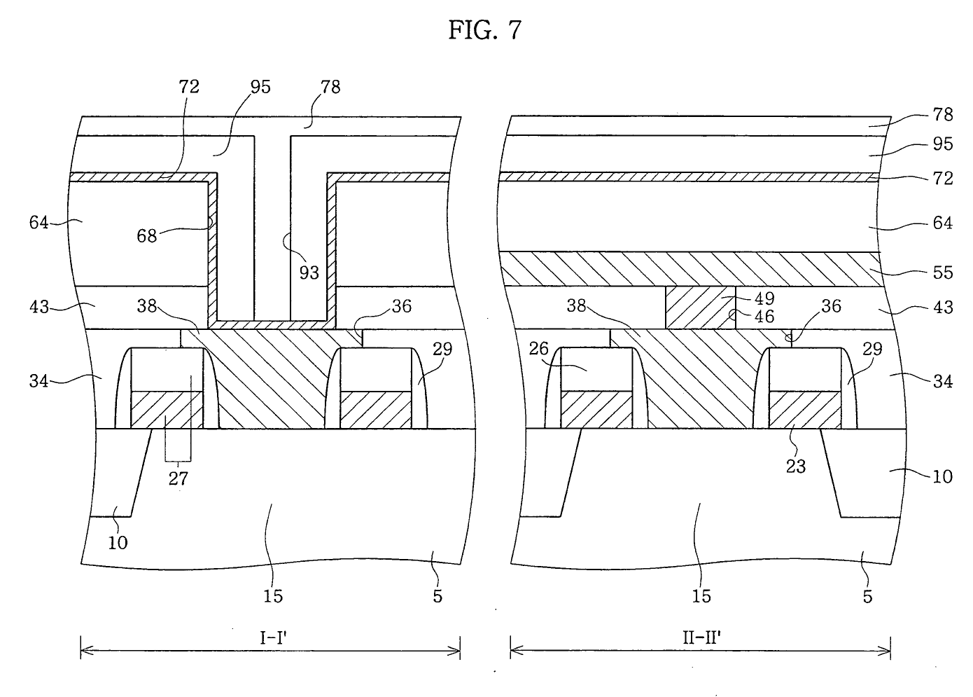

FIGS. 7 to 9 contain cross-sectional views taken along lines I-I′ and II-II′ of FIG. 1, which illustrate a method of forming a semiconductor device according to a second exemplary embodiment of the present invention.

Referring to FIGS. 1 and 7, a molding layer 95 is formed on the node defining layer 72. The molding layer 95 may be formed on the node defining layer 72 to fill the node holes 68. The molding layer 95 may be formed of silicon oxide. A photoresist layer is formed on the node defining layer 72. The photoresist layer may be formed by performing a well known semiconductor photolithography process. The photoresist layer may be formed to have openings, which are aligned with the node holes 68. Here, the diameter of the respective openings may be formed to have a smaller size than that of the respective node holes 68.

The molding layer 95 is etched through the openings using the photoresist layer and the node defining layer 72 as an etch mask and an etch stop layer, respectively, thereby forming molding holes 93. The molding holes 93 may be formed to pass through the node holes 68, respectively. Accordingly, the molding holes 93 may be formed to partially expose the node defining layer 72 through the node holes 68. The photoresist layer is removed from the molding layer 95. Alternatively, the forming of the molding holes 93 may comprise depositing at least one material layer on the molding layer 95, and performing a self-alignment process on the material layers and the molding layer 95. Subsequently, a node insulating layer 78 is formed on the molding layer 95 to fill the molding holes 93.

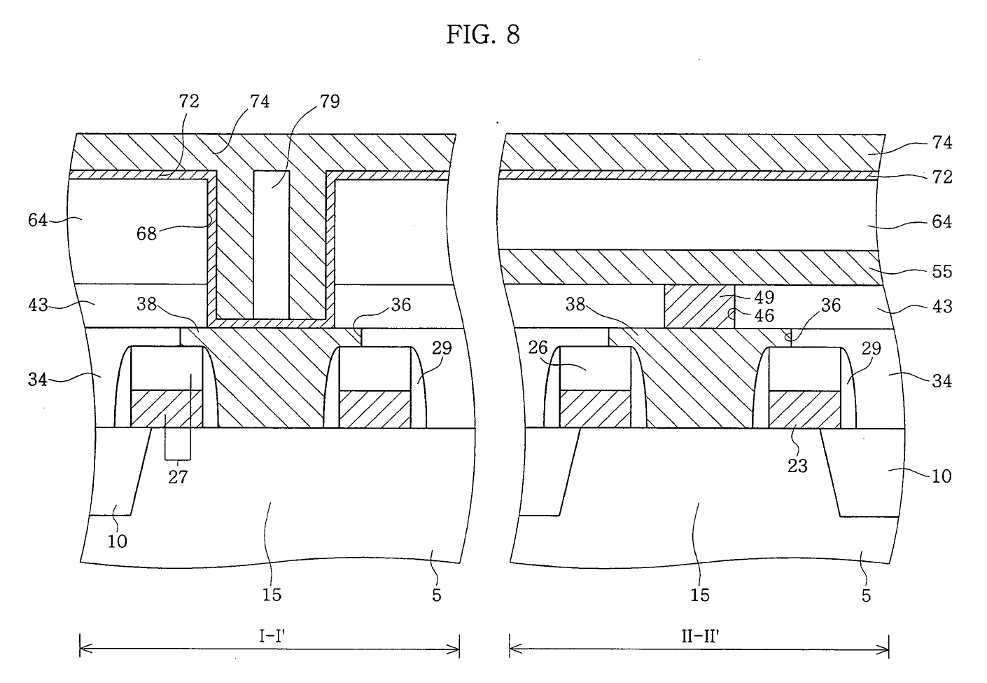

Referring to FIGS. 1 and 8, the node insulating layer 78 and the molding layer 95 are sequentially etched to expose the node defining layer 72, thereby forming a molding pattern (not illustrated) and a preliminary node insulating pattern 79 in the respective node holes 68. The molding pattern may be formed from the molding layer 95. Accordingly, the molding pattern may be formed around the preliminary node insulating pattern 79. The molding pattern is removed using the preliminary node insulating pattern 79 and the node defining layer 72 as an etch stop layer. The molding pattern may be removed using an etchant having a high etch rate with respect to silicon oxide. A node conductive layer 74 is formed to cover the node defining layer 72 and the preliminary node insulating pattern 79, and sufficiently fill the node holes 68.

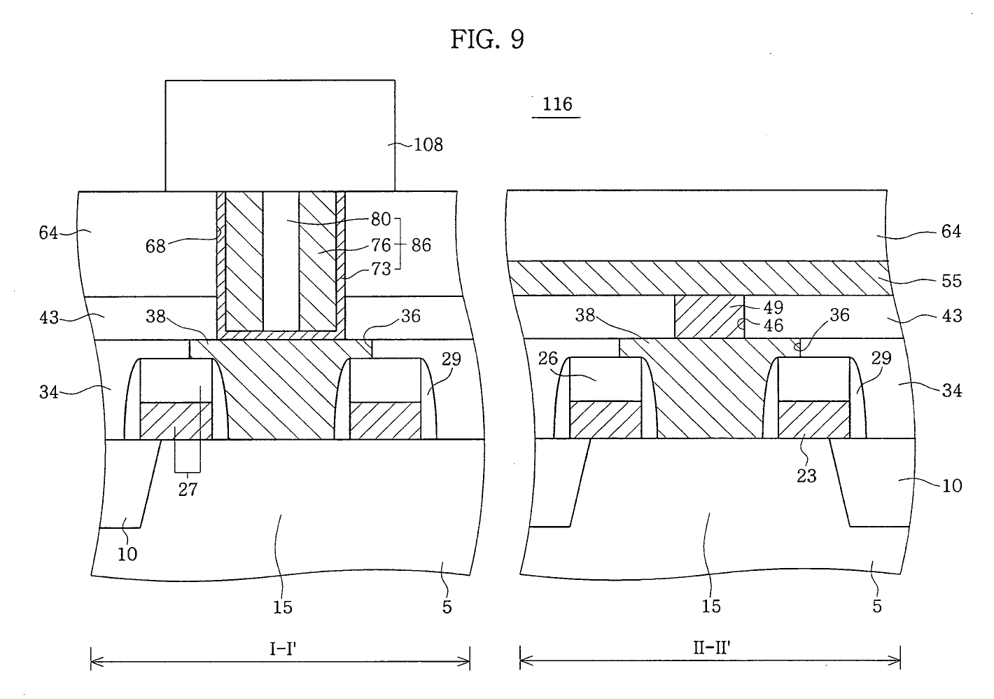

Referring to FIGS. 1 and 9, a planarization process is performed on the node conductive layer 74, the preliminary node insulating pattern 79, and the node defining layer 72 to expose the planarization interlayer insulating layer 64. The planarization process forms a node defining pattern 73, a node conductive pattern 76, and a node insulating pattern 80 in each node hole 68. Here, the node conductive pattern 76 may be formed along a sidewall of the node insulating pattern 80. The node defining pattern 73 may be formed under the node conductive pattern 76 and the node insulating pattern 80, and to surround the node conductive pattern 76 and the node insulating pattern 80.

The node defining pattern 73, the node conductive pattern 76, and the node insulating pattern 80 may be formed to have top surfaces disposed at substantially the same level, respectively. Also, the top surfaces of the node defining pattern 73, the node conductive pattern 76, and the node insulating pattern 80 may be formed to be disposed at substantially the same level as the top surface of the planarization interlayer insulating layer 64. Thus, the planarization interlayer insulating layer 64 may be formed to have no step height with the node defining pattern 73, the node conductive pattern 76, and the node insulating pattern 80. The node defining pattern 73, the node conductive pattern 76, and the node insulating pattern 80 may constitute a node structure 86 according to the second exemplary embodiment of the present invention. Moreover, capacitors 108 may be formed on the planarization interlayer insulating layer 64 to be in contact with the node structures 86, respectively. The capacitors 108 may be formed to have the same structure as that of the first embodiment of the present invention. Thus, a FRAM device 116 according to the second exemplary embodiment of the present invention may be formed.

A method of forming a semiconductor device according to a third exemplary embodiment of the present invention will now be described. Here, the third exemplary embodiment of the present invention may be realized differently than the second embodiment of the present invention when the preliminary node insulating pattern is formed on the node defining layer in FIG. 8. The preliminary node insulating pattern will be referred to as a first preliminary node insulating pattern in the third exemplary embodiment of the present invention. The same reference numerals and symbols will be used for the same elements as those of the first exemplary embodiment of the present invention.

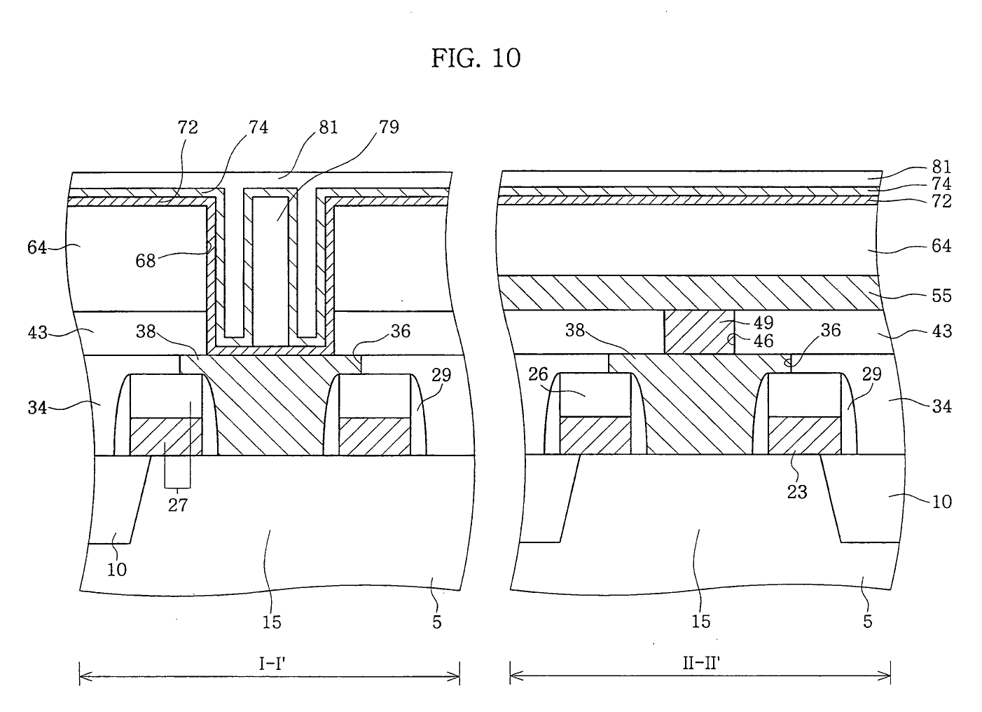

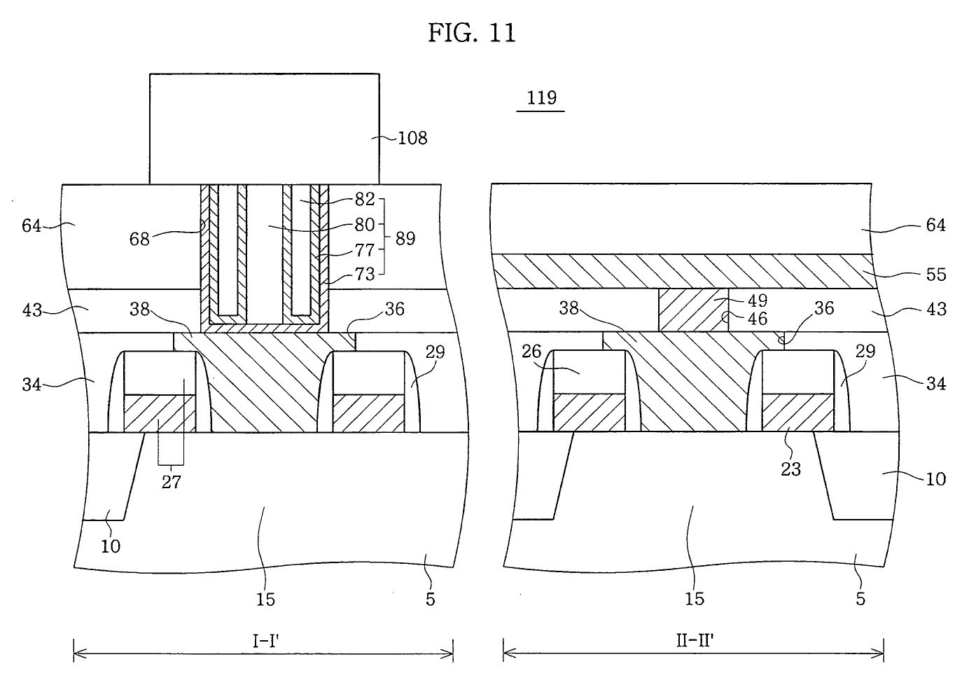

FIGS. 10 and 11 contain cross-sectional views taken along lines I-I′ and II-II′ of FIG. 1, which illustrate a method of forming a semiconductor device according to a third exemplary embodiment of the present invention.

Referring to FIGS. 1 and 10, a node conductive layer 74 and a second node insulating layer 81, which are sequentially stacked, are formed on a first preliminary node insulating pattern 79 and a node defining layer 72 to sufficiently fill the node holes 68. Here, the node conductive layer 72 may be formed in the node holes 68 to conformally cover the node defining layer 72 and the first node insulating patterns 79. The second node insulating layer 81 may be formed on the node conductive layer 74 to sufficiently fill the node holes 68.

Referring to FIGS. 1 and 11, a planarization process is performed on the second node insulating layer 81, the first preliminary node insulating pattern 79, the node conductive layer 74 and the node defining layer 72 to expose the planarization interlayer insulating layer 64. The planarization process may form the node defining pattern 73, the node conductive pattern 77, and the first and second node insulating patterns 80 and 82 in each node hole 68.

The second node insulating pattern 82 may be formed adjacent to a sidewall of the first node insulating pattern 80 to surround the first node insulating pattern 80. The node conductive pattern 77 may be formed under the second node insulating pattern 82, to extend along a sidewall of the second node insulating pattern 82 and to be between the first node insulating pattern 80 and the second node insulating pattern 82. The node defining pattern 73 may be formed under the node conductive pattern 77, and the first and second node insulating patterns 80 and 82 to surround the node conductive pattern 77, and the first and second node insulating patterns 80 and 82. The first and second node insulating patterns 80 and 82, the node conductive pattern 77, and the node defining pattern 73 may be formed to have top surfaces which are disposed at substantially the same level.

Also, the top surfaces of the first and second node insulating patterns 80 and 82, the node conductive pattern 77, and the node defining pattern 73 may be formed to be disposed at substantially the same level as the top surface of the planarization interlayer insulating layer 64. Thus, the planarization interlayer insulating layer 64 may be formed to have no step height with the first and second node insulating patterns 80 and 82, the node conductive pattern 77, and the node defining pattern 73. The first and second node insulating patterns 80 and 82, the node conductive pattern 77, and the node defining pattern 73 may constitute a node structure 89 according to the third exemplary embodiment of the present invention. Moreover, capacitors 108 are formed on the planarization interlayer insulating layer 64 to be in contact with the node structures 89, respectively. The capacitors 108 may be formed to have the same structure as that of the first or second embodiment of the present invention. Thus, a FRAM device 119 according to the third exemplary embodiment of the present invention may be formed.

As described above, node structures under a capacitor in a FRAM device and methods of forming the same are provided. Thus, electrical characteristics of the FRAM device may be improved using the node structures.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A node structure comprising:
a node insulating pattern disposed on a semiconductor substrate;
a node conductive pattern disposed under the node insulating pattern, and extending along a sidewall of the node insulating pattern; and
a node defining pattern disposed under the node conductive pattern, and extending along a sidewall of the node conductive pattern, wherein the node insulating pattern, the node conductive pattern, and the node defining pattern have top surfaces disposed at substantially the same level.

2. The node structure according to claim 1, wherein the node defining pattern comprises titanium nitride (TiN), or titanium nitride and titanium (TiN/Ti) which are sequentially stacked.

3. The node structure according to claim 1, wherein the node conductive pattern comprises tungsten (W).

4. The node structure according to claim 1, wherein the node insulating pattern comprises silicon nitride (Si₃N₄), titanium nitride (TiN), or titanium aluminum nitride (TiAlN).

5. A node structure comprising:
a node insulating pattern disposed on a semiconductor substrate;
a node conductive pattern disposed along a sidewall of the node insulating pattern; and
a node defining pattern disposed under the node conductive pattern and the node insulating pattern, and disposed to surround the node conductive pattern and the node insulating pattern, wherein the node insulating pattern, the node conductive pattern, and the node defining pattern have top surfaces disposed at substantially the same level.

6. The node structure according to claim 5, wherein the node defining pattern comprises titanium nitride (TiN), or titanium nitride and titanium (TiN/Ti) which are sequentially stacked.

7. The node structure according to claim 5, wherein the node conductive pattern comprises tungsten (W).

8. The node structure according to claim 5, wherein the node insulating pattern comprises silicon nitride (Si₃N₄), titanium nitride (TiN), or titanium aluminum nitride (TiAlN).

9. A node structure comprising:
a first node insulating pattern and a second node insulating pattern disposed on a semiconductor substrate, the second node insulating pattern being adjacent to a sidewall of the first node insulating pattern;
a node conductive pattern disposed under the second node insulating pattern, and extending along a sidewall of the second node insulating pattern; and
a node defining pattern disposed under the node conductive pattern and the first and second node insulating patterns, and surrounding the node conductive pattern and the first and second node insulating patterns, wherein the first and second node insulating patterns, the node conductive pattern, and the node defining pattern have top surfaces disposed at substantially the same level.

10. The node structure according to claim 9, wherein the node defining pattern comprises titanium nitride (TiN), or titanium nitride and titanium (TiN/Ti) which are sequentially stacked.

11. The node structure according to claim 9, wherein the node conductive pattern comprises tungsten (W).

12. The node structure according to claim 9, wherein the first and second node insulating patterns comprise silicon nitride (Si₃N₄), titanium nitride (TiN), or titanium aluminum nitride (TiAlN).

13. A method of forming a node structure, comprising:
forming an interlayer insulating layer on a semiconductor substrate;
forming a node hole in the interlayer insulating layer to expose the semiconductor substrate;
forming a node defining layer, a node conductive layer, and a node insulating layer, which sufficiently fill the node hole and are sequentially stacked on the interlayer insulating layer, the node conductive layer and the node defining layer being formed to conformally cover the node hole; and
sequentially etching the node insulating layer, the node conductive layer, and the node defining layer so as to expose the interlayer insulating layer, and to form a node defining pattern, a node conductive pattern, and a node insulating pattern in the node hole,
top surfaces of the node insulating pattern, the node conductive pattern, and the node defining pattern being formed at substantially the same level as a top surface of the interlayer insulating layer.

14. The method according to claim 13, wherein the node defining layer comprises titanium nitride (TiN), or titanium nitride and titanium (TiN/Ti) which are sequentially stacked.

15. The method according to claim 13, wherein the node conductive layer and the interlayer insulating layer comprise tungsten (W) and silicon oxide (SiO₂), respectively.

16. The method according to claim 13, wherein the node insulating layer comprises silicon nitride (Si₃N₄), titanium nitride (TiN), or titanium aluminum nitride (TiAlN).

17. The method according to claim 13, wherein the forming of the node hole comprises:
forming a photoresist layer on the interlayer insulating layer, the photoresist layer being formed to have an opening:
etching the interlayer insulating layer through the opening using the photoresist layer as an etch mask; and
removing the photoresist layer from the semiconductor substrate.

18. A method of forming a node structure, comprising:
forming an interlayer insulating layer on a semiconductor substrate;
forming a node hole in the interlayer insulating layer to expose the semiconductor substrate;
sequentially forming a node defining layer and a molding layer on the interlayer insulating layer to sufficiently fill the node hole;
forming a molding hole in the molding layer to expose the node defining layer, the molding hole being formed to pass through the node hole;
forming a node insulating layer on the molding layer to sufficiently fill the molding hole;
sequentially etching the node insulating layer and the molding layer so as to expose the node defining layer, and to form a molding pattern and a preliminary node insulating pattern in the node hole;
removing the molding pattern using the preliminary node insulating pattern and the node defining layer as an etch stop layer;
forming a node conductive layer, which covers the preliminary node insulating pattern and the node defining layer and sufficiently fills the node hole; and
etching the node conductive layer, the preliminary node insulating pattern, and the node defining layer so as to expose the interlayer insulating layer, and to form a node defining pattern, a node conductive pattern, and a node insulating pattern in the node hole,
top surfaces of the node insulating pattern, the node conductive pattern, and the node defining pattern being formed at substantially the same level as a top surface of the interlayer insulating layer.

19. The method according to claim 18, wherein the node defining layer comprises titanium nitride (TiN), or titanium nitride and titanium (TiN/Ti) which are sequentially stacked.

20. The method according to claim 18, wherein the node conductive layer comprises tungsten (W), and the interlayer insulating layer and the molding layer comprise silicon oxide (SiO₂).

21. The method according to claim 18, wherein the node insulating layer comprises silicon nitride (Si₃N₄), titanium nitride (TiN), or titanium aluminum nitride (TiAlN).

22. The method according to claim 18, wherein forming the molding hole comprises:
forming a photoresist layer on the molding layer, the photoresist layer being formed to have an opening aligned with the node hole;
etching the molding layer through the opening using the photoresist layer and the node defining layer as an etch mask and an etch stop layer, respectively; and
removing the photoresist layer from the semiconductor substrate.

23. The method according to claim 18, wherein forming the node hole comprises:
forming a photoresist layer on the interlayer insulating layer, the photoresist layer being formed to have an opening:
etching the interlayer insulating layer through the opening using the photoresist layer as an etch mask; and
removing the photoresist layer from the semiconductor substrate.

24. A method of forming a node structure, comprising:
forming an interlayer insulating layer on a semiconductor substrate;
forming a node hole in the interlayer insulating layer to expose the semiconductor substrate;
sequentially forming a node defining layer and a molding layer on the interlayer insulating layer to sufficiently fill the node hole;
forming a molding hole in the molding layer to expose the node defining layer, the molding hole being formed to pass through the node hole;
forming a first node insulating layer on the molding layer to sufficiently fill the molding hole;
sequentially etching the first node insulating layer and the molding layer so as to expose the node defining layer, and to form a molding pattern and a first preliminary node insulating pattern in the node hole;
removing the molding pattern using the first preliminary node insulating pattern and the node defining layer as an etch stop layer;
sequentially forming a node conductive layer and a second node insulating layer on the first preliminary node insulating pattern and the node defining layer to sufficiently fill the node hole, the node conductive layer being formed to conformally cover the first preliminary node insulating pattern and the node defining layer; and
sequentially etching the second node insulating layer, the node conductive layer, the first preliminary node insulating pattern, and the node defining layer so as to expose the interlayer insulating layer, and to form a node defining pattern, a node conductive pattern, and first and second node insulating patterns in the node hole, wherein the first and second node insulating patterns, the node conductive pattern, and the node defining pattern are formed to have top surfaces disposed at substantially the same level.

25. The method according to claim 24, wherein the node defining layer comprises titanium nitride (TiN), or titanium nitride and titanium (TiN/Ti) which are sequentially stacked.

26. The method according to claim 24, wherein the node conductive layer comprises tungsten (W), and the interlayer insulating layer and the molding layer comprise silicon oxide (SiO₂).

27. The method according to claim 24, wherein the first and second node insulating layers comprise silicon nitride (Si₃N₄), titanium nitride (TiN), or titanium aluminum nitride (TiAlN).

28. The method according to claim 24, wherein forming the molding hole comprises:
forming a photoresist layer on the molding layer, the photoresist layer being formed to have an opening aligned with the node hole;
etching the molding layer through the opening using the photoresist layer and the node defining layer as an etch mask and an etch stop layer, respectively; and
removing the photoresist layer from the semiconductor substrate.

29. The method according to claim 24, wherein the forming of the node hole comprises:
forming a photoresist layer on the interlayer insulating layer, the photoresist layer being formed to have an opening:
etching the interlayer insulating layer through the opening using the photoresist layer as an etch mask; and
removing the photoresist layer from the semiconductor substrate.
